(19) United States
(12) Patent Application Publication
(10) Pub. No.: US 2026/0011981 A1
(43) Pub. Date: Jan. 8, 2026

(54) Stabilized Diode Laser for Laser-Driven Light Source

(71) Applicants: Hamamatsu Photonics K.K., Hamamatsu-Shi (JP); Energetiq Technology, Inc., Wilmington, MA (US)

(72) Inventor: Shaival Vipul Buch, Watertown, MA (US)

(73) Assignees: Hamamatsu Photonics K.K., Hamamatsu-Shi (JP); Energetiq Technology, Inc., Wilmington, MA (US)

(21) Appl. No.: 18/762,124

(22) Filed: Jul. 2, 2024

(51) Int. Cl. H01S 5/20; H01S 5/00; H01S 5/14; H01S 5/40; H05G 2/00

(52) U.S. Cl. CPC H01S 5/2036; H01S 5/005; H01S 5/141; H01S 5/4012; H05G 2/0082

(57) ABSTRACT

A laser-driven light source includes a laser source that generates continuous wave sustaining light includes a diode laser that generates a CW laser beam at an output and an optical element optically coupled to the output of the diode laser. The optical element includes a region that passes a portion of the CW laser beam to the output of the laser source and a reflection region that reflects another portion of the CW laser beam back to the output of the diode laser. The reflection region is configured to select a spatial mode and wavelength of the laser beam generated by the diode laser, thereby generating the CW sustaining light with radiant flux and spectral shape that is stable as a function of time. A gas-filled bulb optically coupled to the output of the laser source such that the generated CW sustaining light sustains a CW plasma in the gas-filled bulb, thereby emitting light with radiant flux and spectral shape stable as a function of time.

The section headings used herein are for organizational purposes only and should not be construed as limiting the subject matter described in the present application in any way.

### INTRODUCTION

Numerous commercial and research applications have need for high brightness light that covers a broad wavelength range. Laser-driven light sources are available that provide high brightness over various spectral ranges that include the extreme UV through visible and into the infrared regions of the spectrum. These light sources need to have high reliability and long lifetimes. Various types of such high-brightness light sources are produced by Energetiq, a Hamamatsu Company, located in Wilmington, MA. The growing adoption of high-brightness light sources, together with an expanding number of applications that use high brightness light, has driven the need for systems that are able to provide a combination of higher brightness with improved spectral and spatial stability.

### SUMMARY

A laser-driven light source includes a laser source that generates continuous wave sustaining light includes a diode laser that generates a CW laser beam at an output and an optical element optically coupled to the output of the diode laser. For example, the diode laser can be a broad area diode laser and can be a single mode laser. For example, the optical element can be a turning mirror, a partially reflecting beam combiner, or an objective lens.

The optical element can be positioned in a far field of the laser beam generated at the output of the laser source. The optical element includes a region that passes a portion of the CW laser beam to the output of the laser source and a reflection region that reflects another portion of the CW laser beam back to the output of the diode laser. For example, the reflection region can be a fiber Bragg grating, a grating mirror, or a stamped aluminum mirror. The reflection region is configured to select a spatial mode and a wavelength of the laser beam generated by the diode laser, thereby generating the CW radiant flux and spectral shape that is stable as a function of time. A shape of the reflection region can be chosen to select a desired spatial mode and wavelength of the laser beam generated by the diode laser. The spectral selectivity of the reflection region can be configured to select a portion of a spectrum of the laser beam. The reflection region can also be chosen to select a spatial mode and a wavelength of the laser beam generated by the diode laser. The wavelength can be at a center wavelength of a fiber Bragg grating. In addition, the shape of the reflection region can be smaller than a shape of the laser beam. Also, the shape and size of the reflection region can be less than or equal to a shape and size of a single mode of an optical fiber.

A gas-filled bulb optically is coupled to the output of the laser source such that the generated CW sustaining light sustains a CW plasma in the gas bulb, thereby emitting light with radiant flux and spectral shape stable as a function of time.

In some embodiments, the laser source includes a second laser diode that generates a second laser beam at an output and a second optical element optically coupled to the output of the second diode laser, where the second optical element includes a region that directs a portion of the laser beam to the output of the laser source and a reflection region that reflects another portion of the laser beam back to the output of the diode laser, wherein the reflection region is configured to select a spatial mode and a wavelength of the second laser beam generated by the second diode laser. The second optical element can include a beam combining element configured to combine the laser beam and the second laser beam.

### BRIEF DESCRIPTION OF THE DRAWINGS

The present teaching, in accordance with preferred and exemplary embodiments, together with further advantages thereof, is more particularly described in the following detailed description, taken in conjunction with the accompanying drawings. The skilled person in the art will understand that the drawings described below are for illustration purposes only. The drawings are not necessarily to scale; emphasis is instead generally being placed upon illustrating principles of the teaching. The drawings are not intended to limit the scope of the Applicant's teaching in any way.

FIG. 1 illustrates a schematic diagram of a laser-driven light source according to the present teaching.

FIG. 2A illustrates packaged laser modules for a continuous-wave (CW) sustaining light source in a laser-driven light source according to the present teaching.

FIG. 2B illustrates a schematic diagram of a packaged laser module of a CW sustaining light source that includes multiple broad-area laser emitter elements inside for a laser-driven light source according to the present teaching.

FIG. 3 illustrates a schematic diagram of a source including multiple broad-area laser emitter elements and associated optical elements that direct and shape optical beams inside a packaged laser module for a laser-driven light source according to the present teaching.

FIG. 4A illustrates a schematic diagram of a side view of a mirror comprising a bonded grating according to the present teaching.

FIG. 4B illustrates a schematic diagram of a front view of the mirror comprising the bonded grating of FIG. 4A.

FIG. 5A illustrates a schematic diagram of a side view of a mirror comprising a fiber Bragg grating according to the present teaching.

FIG. 5B illustrates a schematic diagram of a front view of the mirror comprising the fiber Bragg grating of FIG. 5A.

FIG. 6 illustrates a schematic diagram of a stabilized CW sustaining light source that comprises multiple broad-area laser emitter elements and mirrors having bonded gratings according to the present teaching.

FIG. 7 illustrates a schematic diagram of a stabilized CW sustaining light source that comprises multiple broad-area laser emitter elements and mirrors having fiber Bragg gratings according to the present teaching.

FIG. 8 illustrates a schematic diagram of a stabilized CW sustaining light source with multiple broad-area laser emitter elements and an objective lens comprising stamped aluminum mirrors according to the present teaching.

FIG. 9 illustrates a schematic diagram of a stabilized CW sustaining light source that comprises multiple broad-area laser emitter elements and a single mode laser and beam splitter according to the present teaching.

### DESCRIPTION OF VARIOUS EMBODIMENTS

The present teaching will now be described in more detail with reference to exemplary embodiments thereof as shown in the accompanying drawings. While the present teaching is described in conjunction with various embodiments and examples, it is not intended that the present teaching be limited to such embodiments. On the contrary, the present teaching encompasses various alternatives, modifications, and equivalents, as will be appreciated by those of skill in the art. Those of ordinary skill in the art having access to the teaching herein will recognize additional implementations, modifications, and embodiments, as well as other fields of use, which are within the scope of the present disclosure as described herein.

Reference in the specification to “one embodiment” or “an embodiment” means that a particular feature, structure, or characteristic described in connection with the embodiment is included in at least one embodiment of the teaching. The appearances of the phrase “in one embodiment” in various places in the specification are not necessarily all referring to the same embodiment.

It should be understood that the individual steps of the method of the present teaching can be performed in any order and/or simultaneously as long as the teaching remains operable. Furthermore, it should be understood that the apparatus and method of the present teaching can include any number or all of the described embodiments as long as the teaching remains operable.

High brightness light sources play an important role in numerous optical measurement and exposure applications. It is desirable that these sources be configured to accommodate numerous use cases. One challenge to broadening the use cases for high-brightness light sources is the requirement to generate high-power and high-brightness light with enhanced stability and higher efficiency. The stability of the optical source that is used to produce the continuous-wave (CW) sustaining light that sustains the plasma is a key factor in this regard. Spatial and/or spectral instability in the sustaining light beam leads to instability in the brightness, spatial and/or spectral properties of the high-brightness light produced by the plasma.

High-power broad-area laser emitter sources can be used to generate CW sustaining light for high-brightness laser-driven light sources. In these broad-area laser emitter sources light from one or more broad-area laser emitters is combined at an output to form the sustaining beam. Broad-area laser emitters can provide high power light with high reliability in a small physical size. Broad-area laser emitters typically have a relatively wide emitter junction in one dimension that supports multiple spatial modes of light that can occupy a relatively large region in the far field and produce a beam pattern that can exhibit multiple lobes. The wide emitter dimension of the broad area laser can be referred to as the slow axis of the emitter, as light diverges less along this axis/dimension. Broad-area laser emitters typically have a narrow emitter dimension perpendicular to the wide emitter dimension that can be referred to as the fast axis, as light diverges quickly from the laser facet along this dimension. The fast axis, or narrow emitter dimension, typically produces a single spatial mode. The multiple spatial modes of the wide emitter dimension can be referred to as lateral modes or transverse modes.

In addition to transverse modes, broad-area laser emitters support numerous longitudinal modes between the front and back laser facets. These multiple longitudinal modes produce many closely spaced spectral lines in the light output of the laser. There is a tendency for mode hopping to occur between, not only the longitudinal modes, but also the transverse, or lateral modes. This mode hopping can result in unstable spatial properties as well as unstable spectral properties of the emitted light. This mode hopping can be temperature dependent and/or laser drive current dependent. Broad-area lasers provide a very high electrical-optical conversion efficiency, and they provide light with high optical output power from a small package. However, mode instabilities in broad-area lasers make them prone to poor spatial beam quality as well as broad and/or unstable spectral quality of the light. These mode instabilities limit their utility for highly stable laser driven light source applications.

It is known that selective optical feedback can be used to reduce mode-hopping. Selective optical feedback can also be used to select desired spatial properties from broad-area laser emitters. The optical feedback can be provided from the output light of the broad-area laser itself. For example, the optical feedback can be provided from a portion of the generated laser beam of the broad-area laser emitter that is in the far-field and directed back into the broad-area laser. Optical feedback can also be provided by light from a laser that is separate from the broad-area laser emitter. Optical feedback light can be used to select and amplify specific groups of lateral modes of the broad-area emitter elements. Optical feedback can also make the far-field output of a broad-area laser relatively single-lobed as compared to the free-running multi-lobed output that emerges when the optical feedback is not present. Furthermore, optical feedback can stabilize the spectral properties of the light output from broad-area laser emitters. This spectral optical feedback can provide more consistent spectral properties over time and/or in the face of changing thermal conditions of the output light from the broad-area lasers.

One feature of the present teaching is the recognition that optical feedback schemes for broad-area lasers can help stabilize the output of laser-driven light sources that use broad-area laser emitters to provide CW sustaining light to the plasma so that their optical flux and spectral shape are stable as a function of time. By optical flux, we mean the radiant energy per unit time.

It is further recognized that it is possible to implement the optical feedback schemes without substantial change and/or increase in size, weight, and/or power requirements. As such, optical feedback schemes can work within existing packaging used for broad-area emitters that produce high-power optical beams and/or high-power light in free space or in an optical fiber at their outputs.

Known approaches to control spectral, angular and/or spatial parameters of broad-area lasers include using external cavities. The external cavities can include tunable external cavities and can include optical cavities with spatial mode filters. Known approaches for stabilizing broad-area lasers also include injection locking using a single element in an array of multiple emitters to provide optical feedback for spectral and spatial stabilization of entire array. Some known approaches for stabilizing broad-area lasers use micro-optic elements for combining beams from multiple laser diodes to increase brightness. Some known approaches for broad-area laser stabilization can also use a phase mask to coherently couple output from multiple laser diodes to increase brightness and beam quality from the combined beam of the multiple lasers. However, to date, approaches to stabilizing broad-area laser emitters have not been applied to generation of stable sustaining light for plasmas. Furthermore, architectures and technologies that are compatible with existing packaging and power considerations needed for laser-driven light sources have not been developed.

One feature of the present teaching is the adaptation of broad-area laser stabilization in order to make them suitable for the high output powers and/or large laser drive currents that are found in laser-driven light sources. It is important that the broad-area stabilization for laser-driven light sources address the particular spectral properties and/or spectral stability needed in CW sustaining light for plasmas. It is also important that the broad-area stabilization techniques applied use approaches to address the particular spatial properties and/or spatial stability needed in CW sustaining light for plasmas. Furthermore, it is important that the broad-area stabilization techniques can be implemented without substantial change to the existing footprint and optical power delivery to the plasmas used in known CW sustaining light sources.

One feature of the present teaching is the recognition that improving the spatial (transverse modes) and spectral (longitudinal modes) stability of a multi-emitter diode laser package can make a plasma light output more stable. This improvement in plasma light output stability improves the efficiency and the brightness available from a laser-driven light source. Improved spatial and spectral stability of the multi-emitter diode laser package can be done through passive or active means that are built into the existing broad-area laser diode package without significant added complexity and/or cost.

FIG. 1 illustrates a schematic diagram of a laser-driven light source 100 according to the present teaching. Continuous-wave sustaining light 102 in an optical beam 104 from a high power laser source (not shown) is focused using focusing optics 106. The focused light is incident to a bulb 108, that can be a proprietary bulb that can include windows that pass the wavelengths of the sustaining light 102. A high intensity plasma is produced in a plasma region 110. The high intensity plasma can be ignited using electrodes 112. In the presence of the CW sustaining light 102, the plasma will persist and generate broadband output light 114. Spectral and spatial stability of the sustaining light 102 will directly affect the spectral and spatial stability of the broadband output light 114. The broadband high-brightness output light 114 can be used for numerous different applications. These applications often rely upon different properties of the broadband light output 114. This includes, for example, power, spectral bandwidth, spectral flatness, spatial uniformity, output numerical aperture and other features of the broadband light output 114. As such, stabilization techniques that provide control over spectral and spatial features of the CW sustaining light 102 are desirable because they can directly affect the power, spectral bandwidth, spectral flatness, spatial uniformity, output numerical aperture and/or other features of the broadband light output 114.

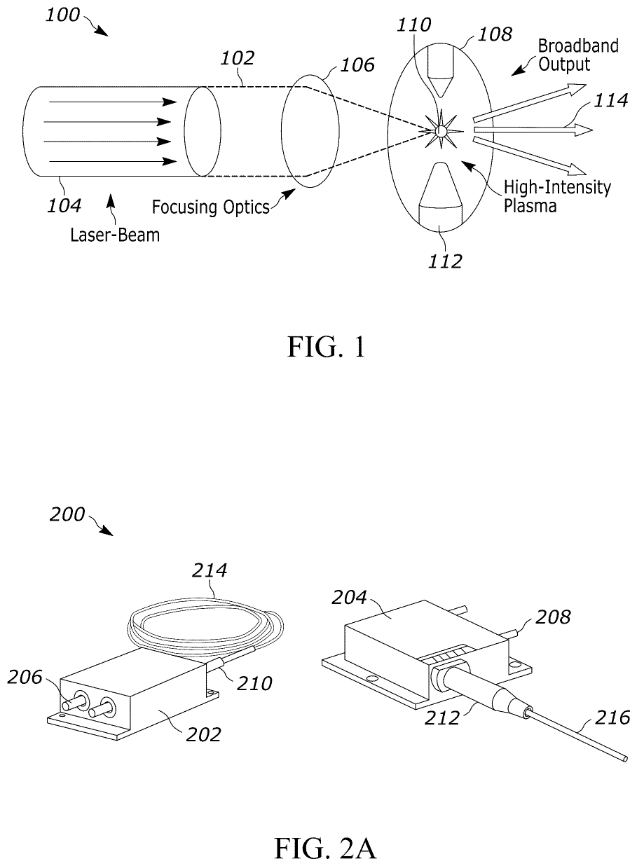

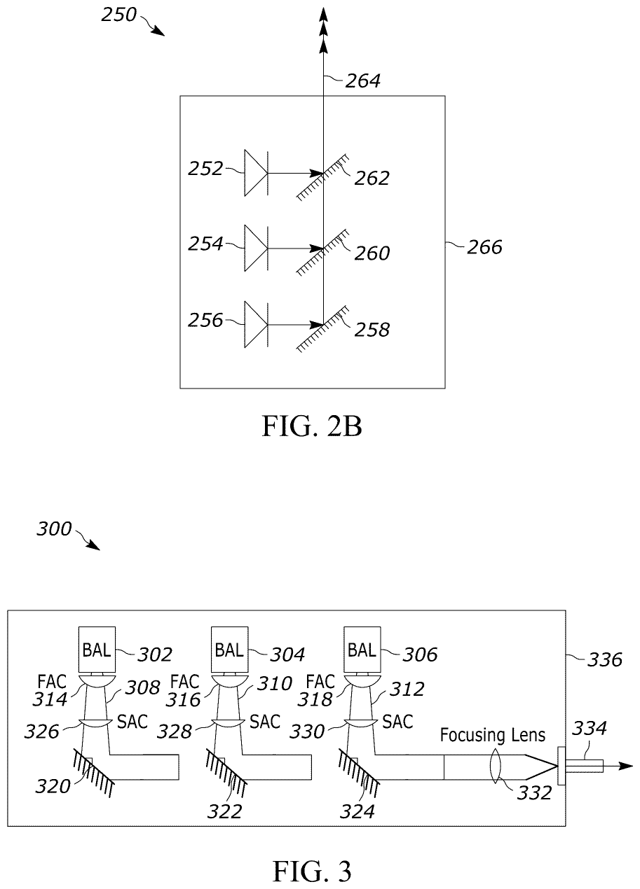

FIG. 2A illustrates packaged laser modules 200 of CW sustaining light sources in a laser-driven light source according to the present teaching. The packages feature an outer case 202, 204, with electrical ports 206, 208 used to apply bias current and control signals to the lasers. There are optical output ports 210, 212 that can include an optical fiber pigtail 214, 216. Inside these packaged laser modules 200 there are typically multiple single-emitter diode lasers whose beams are combined to provide high-power output at the output optical ports 210, 212. This combined high-power light is directed as a CW sustaining light to a plasma region. For example, the light in the fiber pigtail 214, 216 forms the continuous-wave sustaining light 102 in an optical beam 104 that sustains a plasma in the plasma region 110 of the laser driving light source 100 described in connection with FIG. 1.

FIG. 2B illustrates a schematic diagram of a packaged laser module 250 of a CW sustaining light source that includes multiple broad-area laser emitter elements inside for a laser-driven light source according to the present teaching. Three broad-area laser emitters 252, 254, 256 produce high power optical beams. In some embodiments, the laser emitters 252, 254, 256 comprise high-power (e.g. 10s-100s of Watts) semiconductor diode lasers. The high power optical beams are directed to an output using various micro-optical elements. For example, a mirror 258 and beam combiners 260, 262 can be used to project the optical beams from the three laser emitters 252, 254, 256 to a combined beam along a common axis at an output 264. All the optical elements, including lasers 252, 254, 256 and micro-optical elements 258, 260, 262 can be in a common module package 266.

The packaged laser module 250 produces light at the output 264 to sustain a plasma which emits broadband light as part of a laser-driven light source (not shown). Instability in the light at the output 264 means there will be instability in the light output that the end-user of the light source (not shown) experiences. Instability of the output light can mean, for example, that the high-brightness light output is not power-stable over time and/or is not spatially uniform and/or is not spectrally stable. One feature of the present teaching is the recognition that using only minor modifications to one or more of the micro-optical elements 258, 260, 262 can improve the stability of one or more of the broad-area laser emitters 252, 254, 256, thus improving the performance of a laser-driven light source that derives sustaining light from the packaged laser module 250.

FIG. 3 illustrates a schematic diagram of a source 300 including multiple broad-area laser (BAL) emitter elements 302, 304, 306 and associated optical elements that direct and shape optical beams generated by the BAL emitters 302, 304, 306 that are inside a packaged laser module 336 for a CW sustaining light source in a laser-driven light source according to the present teaching. Three broad-area lasers 302, 304, 306 generate three optical beams 308, 310, 312 at an output. Each of the three optical beam 308, 310, 312 is shaped at the output using a lens 314, 316, 318. In some embodiments, the lens 314, 316, 318 can be a fast-axis collimating lens (FAC). The FAC lenses collimate light spreading from a semiconductor laser in the fast-axis direction. The beams 308, 310, 312 are steered and/or combined using a mirror 320 and beam combiners 322, 324. The beams 308, 310, 312 are each shaped by passing through a second lens 326, 328, 330. In some embodiments, the lens 326, 328, 330 can be a slow-axis collimating lens (SAC). These SAC lenses collimate light spreading from a semiconductor laser in the slow-axis direction. After passage through the second lens 326, 328, 330, the optical beams 308, 310, 312 are nominally collimated in two-dimensions. The combined nominally-collimated beams 308, 310, 312 are focused by a lens 332. The lens 332 can be a coupling lens that couples the beams 308, 310, 312 into an optical fiber 334 at an output of the module package 336. The source 300 of FIG. 3, as well as other sources of sustaining light described herein illustrate the use of three emitter elements 302, 304, 306. However, it should be understood that different numbers of emitter elements can also be used.

One feature of the present teaching is the recognition that the architecture of this module 300 supports the addition of optical feedback elements with very little modification. This includes, for example, the recognition that it is possible to reuse one or more of the lenses 314, 316, 318, 326, 328, 330, 332 and/or one of more of the mirror 320 and the combiners 322, 324. Detailed examples of embodiments of the modifications to provide optical feedback are described in more detail below.

The use of optical feedback improves beam quality from the output of the broad area lasers 302, 304, 306. For example, optical beam widths can be narrowed by the use of optical feedback. In one specific example, beam widths of less than one degree can be provided with optical feedback as compared to over a 5-degree beam widths from a free-running broad-area laser emitter output. In general, it is possible to select and amplify various groups of lateral modes if a mirror is placed in a far field plane at a particular lateral offset from the center of the free-running beam. In some cases, a mirror position with a particular offset is associated with a particular desired beam width and associated power efficiency.

As another example, optical feedback can be used to modify the spectral behavior of the optical output from the broad area lasers 302, 304, 306. Spectral mode hopping can be reduced. Center wavelength, or wavelengths, of operation can be selected. Emission wavelengths can be stabilized and/or selected. Spectral bandwidths can be selected, reduced and/or controlled. Spectral bandwidths of the output of the broad area lasers 302, 304, 306 with optical feedback can be narrower than spectral bandwidths of the output of the broad area lasers 302, 304, 306 without optical feedback. The use of optical feedback can reduce the effects of thermal changes on the spectral output of the broad area lasers 302, 304, 306. For example, a wavelength of emission of the output of the broad area lasers 302, 304, 306 without optical feedback can change as a function of temperature by a particular value of nanometers-per-degree. A wavelength of emission of the output of the broad area lasers 302, 304, 306 with optical feedback can change as a function of temperature by a lower value of nanometers-per-degree. For example, the wavelength of emission of the output of the broad area lasers 302, 304, 306 without optical feedback can change as a function of temperature by a few nanometers per Ten-Degree-Celsius temperature change. The wavelength of emission of the output of the broad area lasers 302, 304, 306 without optical feedback can change as a function of temperature by less than a nanometer per Ten-Degree-Celsius temperature change. Spectral control is provided by the use of spectrally selective optical feedback. In some embodiments, a combination of both selective spatial feedback and selective spectral feedback is used.

Optical feedback for the broad area lasers 302, 304, 306 can be produced in various ways that spatially and/or spectrally select portions of the output from the broad-area laser in the far field. For example, small sized mirrors, less than a beam size, can be used to provide selective spatial feedback. Large gratings, greater than a beam size, can also be used to provide spectral feedback. Small size gratings, less than a beam size, can also be used to provide a combination of spatial and spectral feedback.

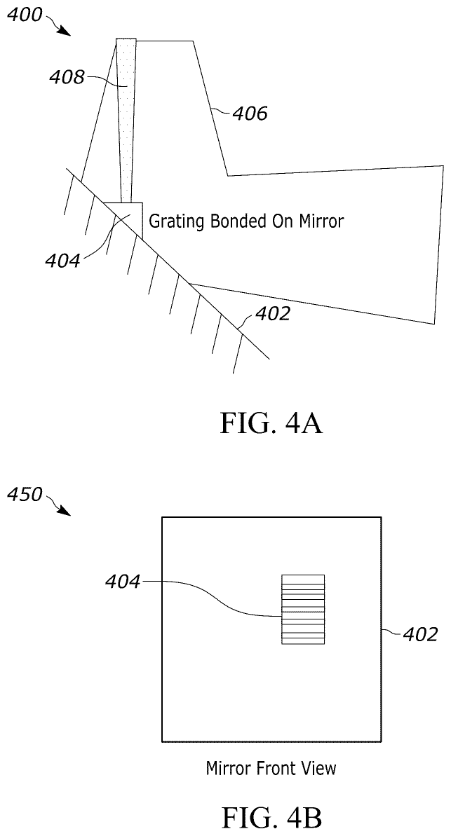

FIG. 4A illustrates a schematic diagram of a side view 400 of a mirror 402 comprising a bonded grating 404 according to the present teaching. The grating 404 is sized to select a portion of the incoming laser beam 406 to provide an optical feedback beam 408 that is directed back to the laser (not shown). A position of the grating 404 within the laser beam 406 and the spectral properties of the grating 404 can be chosen to produce a desired beam profile and/or spectral beam property of the output from the laser in the far field.

FIG. 4B illustrates a schematic diagram of a front view 450 of the mirror 402 comprising the bonded grating 404 of FIG. 4A. The bonded grating 404 size is only a small fraction of the mirror 402 size, thereby limiting the loss of the optical power from the beam. The position of the bonded grating 404 on the mirror 404 and with respect to the position, size and shape of the laser beam is selected to provide a desired spatial profile of the laser beam output by the laser when the optical feedback beam 408 is present. In some embodiments, a particular lateral offset to the center of the beam along the slow axis of the laser is chosen for the bonded grating 404 to select a particular spatial mode of the laser.

Thus, the mirror 402 with bonded grating 404 is optically coupled to an output optical beam 406 of a broad area diode laser (not shown), the mirror 402 has a region not occupied by the bonded grating 404 that passes a portion of the output optical beam and has a reflection region, the bonded grating 404, that reflects another portion of the optical beam 406 back to the broad area diode laser as an optical feedback beam 408. The reflection region can be configured to select a spatial mode and a wavelength of the laser beam 406 generated by the broad area diode laser, and as such stabilizes the light in the laser beam 406.

In some embodiments, the bonded grating 404 and mirror 402 can be included as the turning mirror and/or beam combining elements of a multiple broad-area laser source. See, for example, the mirror 320 and/or beam combining elements 322, 324 of module 300 described in connection with FIG. 3.

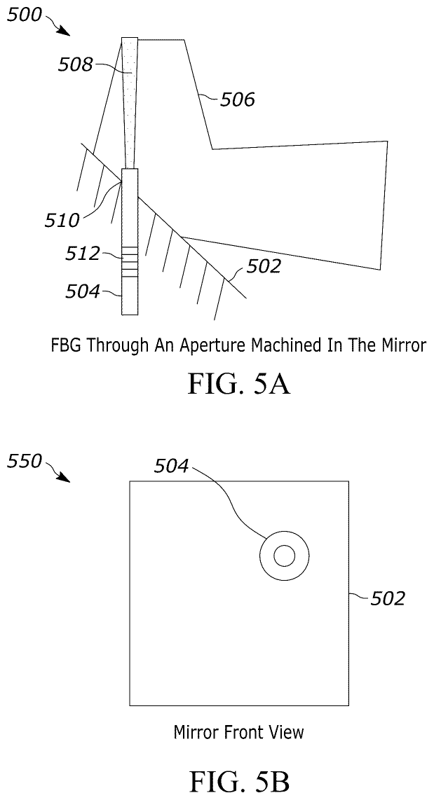

FIG. 5A illustrates a schematic diagram of a side view 500 of a mirror 502 comprising a fiber Bragg grating (FBG) 504 according to the present teaching. The fiber Bragg grating 504 can be a single-mode fiber Bragg grating that is positioned on the mirror 502 to select a desired portion of the incoming laser beam 506 so as to provide an optical feedback beam 508 that is directed back to the laser (not shown). The fiber Bragg grating 504 is inserted in an aperture 510 in the mirror 502. A position of the aperture 510 as well as the grating 504 within the laser beam 506 and the spectral properties of the fiber Bragg grating 504 can be chosen to produce a desired beam profile and/or spectral beam property of the output from the laser in the far field. The fiber Bragg grating is a microstructure 512 with a spatially periodic modulation of the refractive index of the core of the fiber Bragg grating 504. The microstructure 512 is typically a few millimeters in length. Details of the microstructure 512 influence the spectral properties of the grating 504, but generally it acts as a wavelength sensitive mirror that reflects a narrow frequency band and pass the rest of the optical spectrum.

FIG. 5B illustrates a schematic diagram of a front view 550 of the mirror 502 comprising the fiber Bragg grating 504 of FIG. 5A. The fiber Bragg grating 504 size is only a small fraction of the mirror 502 size, thereby limiting the loss of the optical power in the laser beam. The position of the fiber Bragg grating 504 on the mirror 502 with respect to the position, size and shape of the laser beam 506 is selected to provide a desired spatial profile of the laser beam 506 output by the laser. In some embodiments, a particular lateral offset to the center of the beam along the slow axis of the laser is chosen to select a particular spatial mode of the laser. In some embodiments, the fiber Bragg grating 504 and mirror 502 can be the turning mirror and/or beam combining elements of a multiple broad-area laser source, for example, mirror 320 and/or beam combining elements 322, 324 of module 300 of FIG. 3.

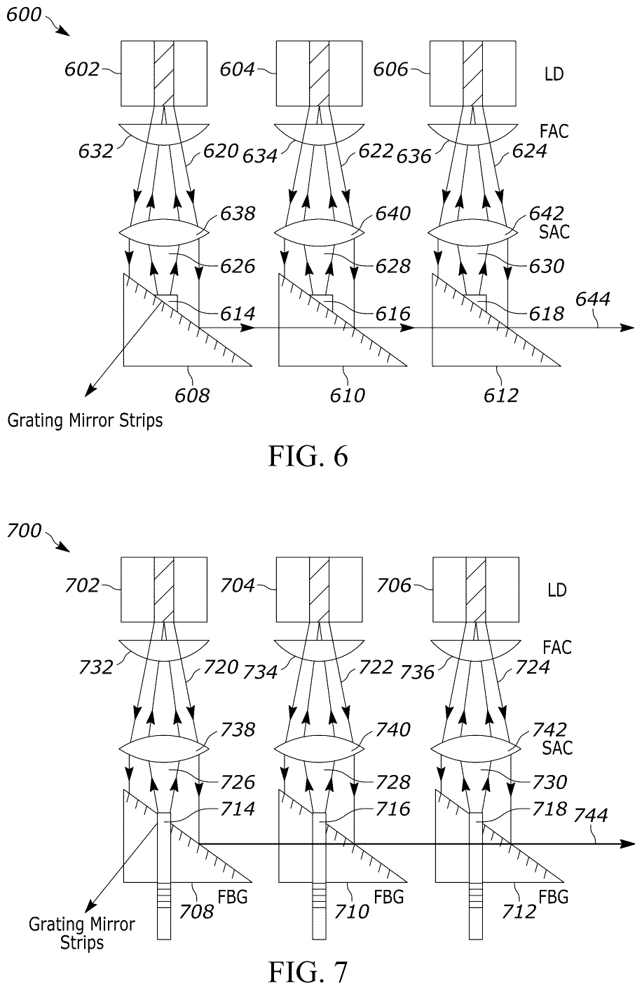

FIG. 6 illustrates a schematic diagram of a stabilized CW sustaining light source 600 that comprises multiple broad-area laser emitter elements 602, 604, 606 and mirrors/combiners 608, 610, 612 having bonded gratings 614, 616, 618 according to the present teaching. The source 600 is stabilized using external optical feedback to provide spatial mode selection in the broad-area laser. The source 600 can also provide wavelength stabilization using spectrally selective grating feedback. The bonded gratings 614, 616, 618 are sized to select a portion of the incoming laser beams 620, 622, 624 to provide optical feedback beams 626, 628, 630 that are directed back to the respective lasers 602, 604, 606. A position of the bonded gratings 614, 616, 618 within the laser beams 620, 622, 624 and the spectral properties of the grating 614, 616, 618 can be chosen to produce a desired beam profile and/or spectral beam property of the output from the laser in the far field.

The three broad-area lasers 602, 604, 606 generate the three optical beams 620, 622, 624 at an output. Each beam 620, 622, 624 is shaped at the laser output using a lens 632, 634, 636. In some embodiments, the lens 632, 634, 636 can be a fast-axis collimating lens that collimate light spreading from a semiconductor laser in the fast-axis direction. The beams 620, 622, 624 are further shaped by passing through a second lens 638, 640, 642. In some embodiments, the second lens 638, 640, 642 can be a slow-axis collimating lens that collimates light spreading from a semiconductor laser in the slow-axis direction. After passage through the second lens 638, 640, 642 the optical beams 620, 622, 624 are nominally collimated in two-dimensions. The beams 620, 622, 624 are steered and/or combined using a mirror 608 or a beam combiner 610, 612. The combined nominally-collimated beams 620, 622, 624 are sent to an output 644, where they can be focused, coupled into a fiber, and/or otherwise optically shaped, directed or otherwise processed before being sent to a plasma region in a laser-driven light source (not shown).

FIG. 7 illustrates a schematic diagram of a stabilized source 700 of CW sustaining light that comprises multiple broad-area laser emitter elements 702, 704, 706 and mirrors/combiners 708, 710, 712 having fiber Bragg gratings 714, 716, 718 according to the present teaching. The source 700 is stabilized using external optical feedback from the fiber Bragg gratings 714, 716, 718 to provide spatial mode selection in the respective broad-area laser 702, 704, 706. The source 700 can also provide wavelength stabilization using spectrally selective grating feedback. The fiber Bragg gratings 714, 716, 718 can be single-mode fiber Bragg gratings. The fiber Bragg gratings 714, 716, 718 can be positioned on the mirrors 708, 710, 712 to select a desired portion of the incoming laser beams 720, 722, 724 to provide an optical feedback beam 726, 728, 730 that is directed back to the laser. The positions of the fiber Bragg gratings 714, 716, 718 can be the same for each mirror/combiner 708, 710, 712 or different. The fiber Bragg gratings 714, 716, 718 can be inserted in an aperture in the respective mirror/combiner 708, 710, 712. A position of the aperture as well as the fiber Bragg gratings 714, 716, 718 within the laser beams 720, 722, 724, and the spectral properties of the fiber Bragg gratings 714, 716, 718 can be chosen to produce a desired beam profile and/or spectral beam property of the output from the respective laser 702, 704, 706 in the far field.

The three broad area lasers 702, 704, 706 generate the three optical beams 720, 722, 724 at an output. Each beam 720, 722, 724 is shaped at the laser output using a lens 732, 734, 736. In some embodiments, the lens 732, 734, 736 can be a fast-axis collimating lens that collimate light spreading from a semiconductor laser in the fast-axis direction. The beams 720, 722, 724 are shaped by passing through a second lens 738, 740, 742. In some embodiments, the second lens 738, 740, 742 can be a slow-axis collimating lens that collimates light spreading from a semiconductor laser in the slow-axis direction. After passage through the second lens 738, 740, 742, the optical beams 720, 722, 724 are nominally collimated in two-dimensions. The beams 720, 722, 724 are steered and/or combined using a mirror 708 or a beam combiner 710, 712. The combined nominally-collimated beams 720, 722, 724 are sent to an output 744, where they can be focused, coupled into a fiber, or otherwise processed before being sent to a plasma region in a laser-driven light source (not shown).

The broad area lasers 702, 704, 706 are stabilized using external optical feedback from a respective fiber Bragg grating 714, 716, 718 to provide spatial mode selection. In some embodiments, the wavelength is stabilized based on the spectral feedback from the fiber Bragg grating 714, 716, 718. In some embodiments, different center wavelengths for each the fiber Bragg grating 714, 716, 718 is used. The wavelength differences can be small. For example, two or more of the fiber Bragg gratings 714, 716, 718 can be centered at different wavelengths, thereby causing laser emission from the broad-area lasers to be centered at different wavelengths.

Embodiments using multiple different wavelengths supports using wavelength beam-combiners for combining the beams from different lasers 702, 704, 706. That is, one or both of beam combiners 710, 712 can be wavelength selective combiners. Such configurations can reduce combining loss. Such configurations also provide additional flexibility in beam positioning using wavelength sensitive beam shaping and steering components (not shown) at the output 744. The use of two or more different wavelengths for the optical feedback can provide more flexibility in spatial properties of the combined beam or beams at the output 744.

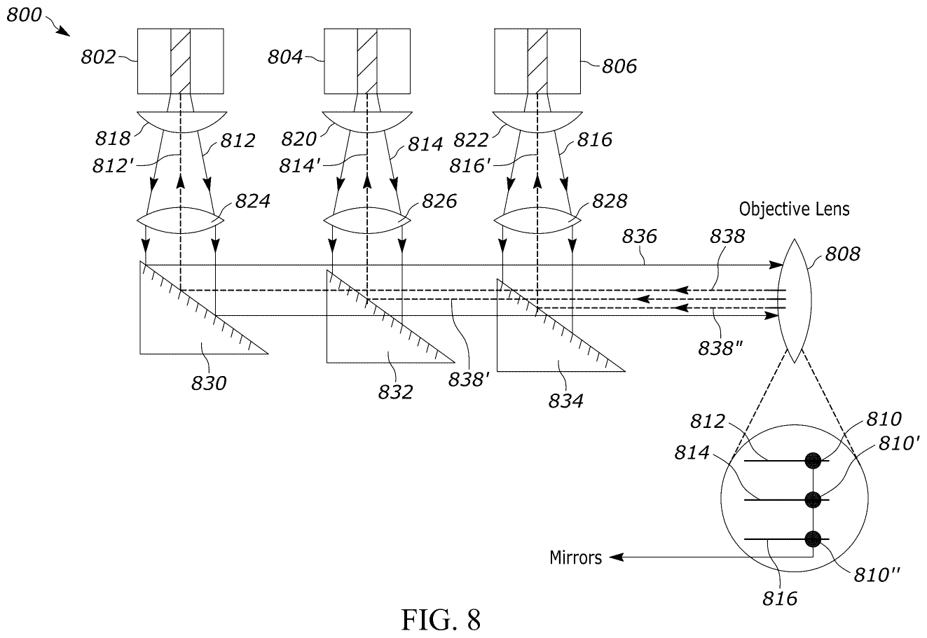

FIG. 8 illustrates a schematic diagram of a stabilized CW sustaining light source 800 that comprises multiple broad-area laser emitter elements 802, 804, 806 and an objective lens 808 with stamped aluminum mirrors 810, 810′, 810″ according to the present teaching. Optical feedback provided by the stamped aluminum mirrors 810, 810′, 810″ provides spatial mode selection of the broad-area laser emitter elements 802, 804, 806. The three broad-area lasers 802, 804, 806 generate three optical beams 812, 814, 816 at their respective outputs. Each beam 812, 814, 816 is shaped using a respective lens 818, 820, 822. In some embodiments, the lens 818, 820, 822 can be a fast-axis collimating lens that collimates light spreading from a semiconductor laser in the fast-axis direction. The beams 812, 814, 816 are shaped by passing through a respective second lens 824, 826, 828. In some embodiments, the second lens 824, 826, 828 can be a slow-axis collimating lens that collimates light spreading from a semiconductor laser in the slow-axis direction. After passage through the second lens 824, 826, 828, the optical beams 812, 814, 816 are nominally collimated in two-dimensions. The beams 812, 814, 816 are steered and/or combined using steering mirrors/combiners 830, 832, 834. The beams 812, 814, 816 are directed to the output objective lens 808.

Mirrors 810, 810′, 810″ that, in some embodiments, are stamped on the surface of the objective lens 808, direct a portion of the combined beam 836 back to the lasers 802, 804, 806. For example, the mirrors 810, 810′, 810″ can be stamped aluminum mirrors. The positions of the mirrors 810, 810′, 810″ are chosen so that a portion of the combined beam 836 from mirror 810 directs optical feedback 838 to a desired spatial mode in laser 802, a portion of the combined beam 836 from mirror 810′ directs optical feedback 838′ to a desired spatial mode in laser 804, and a portion of the combined beam 836 from mirror 810″ directs optical feedback 838″ to a desired spatial mode in laser 806. Embodiments of the present teaching that use multiple mirrors positioned on an output optical element of the source 800, such as an objective lens 808 and stamped mirrors 810, 810′, 810″, are useful to provide locking of multiple lasers.

One skilled in the art will appreciate that the stamped-mirror configuration is scalable, and can be applied to more than three lasers, allowing very high powers to be realized. One feature of the present teaching is that using stamped mirrors also allows for a variety of laser positions. For example, individual lasers, relatively widely spaced, and/or stacked and/or monolithic high-power broad-area laser arrays can be synchronized and/or stabilized using spatial feedback provided from an array of stamped mirrors. When used as a source of sustaining light for a laser-driven light source, these synchronized high-power sources provide higher brightness, more stable spectral properties and/or improved spatial properties than known laser-driven light sources. It is important to note that the paths for the optical feedback 838, 838′, 838″ can utilize the same beam steering and shaping optics that provide the combined beam 836.

One feature of the present teaching is that the broad-area laser sources can be synchronized and/or stabilized using a common source of light for optical feedback. This can be referred to as simultaneous injection locking of multiple semiconductor laser diodes. The broad-area laser diodes may be individual broad-area laser diodes, or broad-area laser diodes configured as a laser diode array. For example, light from one single-mode laser can be split into multiple beams and the individual beams can be directed into different ones of multiple broad-area laser emitters to affect their light output. In particular, it is known that the optical feedback from one single mode laser can be used to lock the frequency and/or phase of the output light from different broad area laser devices. An advantage in using a single mode laser is that the spatial mode is very stable, and the spectral modes can be stable as well. As such, it is possible to use the light from at least one single mode laser to help stabilize the frequency and/or phase of light output from multiple broad-area laser emitters that are being used as sustaining light for a laser-driven light source. A feature of embodiments of the present teaching that use a single source for injection locking of the broad-area lasers is that it can be efficient because only a small amount of optical power is required to achieve locking, and the output power of the locked optical output from the broad area lasers can be many orders of magnitude higher than the injection locking optical power. No light from the broad-area lasers needs to be portioned off to be used for the optical feedback, so that high output power efficiency can be achieved.

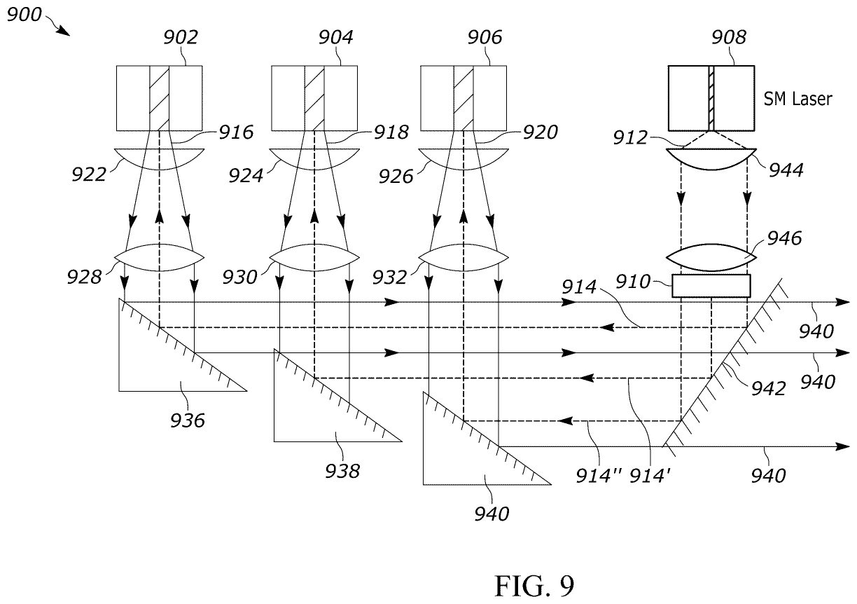

FIG. 9 illustrates a schematic diagram of a stabilized CW sustaining light source 900 that comprises multiple broad-area laser emitter elements 902, 904, 906 and a single mode laser 908 and diffractive optical element 910 for beam shaping according to the present teaching. The single mode laser 908 light output 912 is split into multiple beams 914, 914′, 914″ using the diffractive optical element 910, that can be, for example, a diffractive optical beam splitter element. The individual beams are directed to different broad area laser elements 902, 904, 906. A combination of wavelength and spatial position of each split beam 914, 914′, 914″ can be provided by the diffractive optical element 910. That is because diffractive optical elements can be spectrally selective and also are able to separate and create multiple spatial beams from an incoming spatial beam. These separate beams are coupled into different broad-area laser emitters 902, 904, 906 and provide selective injection locking for each broad-area laser emitter 902, 904, 906. In some embodiments, the spectral output of the single mode laser is single spectral mode with a narrow spectral bandwidth, and in these embodiments, the spatial beams created by the beam splitter have the same spectral properties. In this case the optical output from the different broad-area laser emitters 902, 904, 906 can be frequency and/or phase locked to the common frequency of the single mode laser.

The three broad area lasers 902, 904, 906 generate the three optical beams 916, 918, 920 at an output. Each optical beam 916, 918, 920 is shaped at the laser output using a lens 922, 924, 926. In some embodiments, the lens 922, 924, 926 can be a fast-axis collimating lens that collimates light spreading from a semiconductor laser in the fast-axis direction. The beams 916, 918, 920 are shaped by passing through a second lens 928, 930, 932. In some embodiments, the second lens 928, 930, 932 can be a slow-axis collimating lens that collimates light spreading from a semiconductor laser in the slow-axis direction. After passage through the second lens 928, 930, 932 the optical beams 916, 918, 920 are nominally collimated in two-dimensions. The beams 916, 918, 920 are steered and/or combined using a mirror/combiner 936, 938, 940. The beams 916, 918, 920 are directed to the output beam combiner 942. The single mode laser 908 output beam 912 can also be shaped by two lenses 944, 946 to nominally collimate, or otherwise shape, the spatial properties of the output beam 912.

When a low power single-mode laser 908 is used for injection locking, the spectral output of the combined beam 940 of the synchronized broad area lasers 902, 904, 906 can have spectral bandwidths on the order of the bandwidth of the single mode laser 908. That can be bandwidths of less than 10 MHz, for example. The spatial properties of the combined beam 940 output of the synchronized broad area lasers 902, 904, 906 are more stable over time. A drive current of the single mode laser 908 can be chosen to provide desired characteristics of the output of the synchronized broad area lasers 902, 904, 906. For example, the desired characteristics can be the number of spatial modes in the optical combined beam 940 output, the center frequency of the optical combined beam 940 output, and/or the bandwidth of the optical combined beam 940 output. In addition, the temporal stability of the combined beam 940 output can be controlled by controlling the drive current of the single mode laser 908. It is important to note that the paths for the optical feedback 914, 914′, 914″ can utilize the same beam steering and shaping optics that provide the combined beam 940.

A feature of the present teaching is the use of optical feedback from the slow-axis far-field to generate a narrow far-field emission spectrum that can avoid filamentation in the output beam, thereby improving optical beam quality and/or spatial brightness of the output of the laser-driven light source. By utilizing spectrally selective optical feedback, the system can perform simultaneous wavelength stabilization and thereby improve spectral brightness. Furthermore, the improved wavelength stability results in a more stable light source that results in a more stable plasma.

The architectures of embodiments of the stabilization system of the present teaching allow one to include brightness and stability improvements in both the spatial and spectral domains within a compact direct-diode package while not modifying the fiber coupling optics or the fibers typically used in non-stabilized systems already in use today. The enhanced stability and brightness achieved in stabilized laser-driven light sources of the present teaching lead to lower intensity noise and better spectral repeatability for laser driven plasmas, without requiring a re-design of the bulb or electronics. It is possible, in some embodiments, to use an active alignment step during assembly that aligns the optical feedback paths while monitoring the spectral and/or spatial quality of the combined output optical beam so that the selected alignment provides a desired spatial beam profile and/or spectral property. In some embodiments, the active alignment is used that monitors the high-brightness light from the laser-driven light source to select an alignment of the optical feedback paths to produce a desired brightness of the light output from the laser-driven light source.

### EQUIVALENTS

While the Applicant's teaching is described in conjunction with various embodiments, it is not intended that the Applicant's teaching be limited to such embodiments. On the contrary, the Applicant's teaching encompasses various alternatives, modifications, and equivalents, as will be appreciated by those of skill in the art, which may be made therein without departing from the spirit and scope of the teaching.

What is claimed is:

1. A laser-driven light source comprising:
a) a laser source that generates continuous wave (CW) sustaining light at an output, the laser source comprising:
i) a diode laser that generates a CW laser beam at an output; and
ii) an optical element optically coupled to the output of the diode laser, the optical element comprising a region that passes a portion of the CW laser beam to the output of the laser source and a reflection region that reflects another portion of the CW laser beam back to the output of the diode laser, wherein the reflection region is configured to select a spatial mode and wavelength of the CW laser beam generated by the diode laser, thereby generating the CW sustaining light with radiant flux and spectral shape that is stable as a function of time; and
b) a gas-filled bulb optically coupled to the output of the laser source such that the generated CW sustaining light sustains a CW plasma in the gas-filled bulb, thereby emitting light with radiant flux and spectral shape stable as a function of time.

2. The laser driven light source of claim 1, wherein diode laser comprises a broad area diode laser.

3. The laser driven light source of claim 1, wherein diode laser comprises a single mode diode laser.

4. The laser driven light source of claim 1, wherein dimensions of the reflection region are chosen to select a desired spatial mode and wavelength of the CW laser beam generated by the diode laser.

5. The laser driven light source of claim 1, wherein a shape of the reflection region is chosen to select a desired spatial mode and wavelength of the CW laser beam generated by the diode laser.

6. The laser driven light source of claim 1, wherein a spectral selectivity of the reflection region is chosen to select a desired spatial mode and wavelength of the CW laser beam generated by the diode laser.

7. The laser driven light source of claim 6, wherein the wavelength comprises a center wavelength of a fiber Bragg grating.

8. The laser driven light source of claim 1, wherein a shape of the reflection region is smaller than a shape of the laser beam.

9. The laser driven light source of claim 1, wherein a size of the reflection region is smaller than a size of the laser beam.

10. The laser driven light source of claim 1, wherein a spectral selectivity of the reflection region selects a portion of a spectrum of the CW laser beam.

11. The laser driven light source of claim 1, wherein the optical element is positioned in a far field of the CW laser beam generated at the output of the laser source.

12. The laser driven light source of claim 1, wherein a shape and size of the reflection region are less than or equal to a shape and size of a single mode of an optical fiber.

13. The laser driven light source of claim 1, wherein the optical element comprises a turning mirror.

14. The laser driven light source of claim 1, wherein the optical element comprises a partially reflecting beam combiner.

15. The laser driven light source of claim 1, wherein the optical element comprises an objective lens.

16. The laser driven light source of claim 1, wherein the reflection region comprises a facet of a fiber Bragg grating.

17. The laser driven light source of claim 1, wherein the reflection region comprises a grating mirror.

18. The laser driven light source of claim 1, wherein the reflection region comprises stamped aluminum mirrors.

19. The laser driven light source of claim 1, wherein the laser source further comprises a second diode laser that generates a second CW laser beam at an output and a second optical element optically coupled to the output of the second diode laser, the second optical element comprising a region that directs a portion of the second CW laser beam to the output of the laser source and a reflection region that reflects another portion of the second CW laser beam back to the output of the second diode laser, wherein the reflection region of the second optical element is configured to select a spatial mode and wavelength of the second CW laser beam generated by the second diode laser.

20. The laser driven light source of claim 19 wherein dimensions of the reflection region of the second optical element are chosen to select a desired spatial mode and wavelength of the second CW laser beam generated by the second diode laser.

21. The laser driven light source of claim 19 wherein a shape of the reflection region of the second optical element is chosen to select a desired spatial mode and wavelength of the second CW laser beam generated by the second diode laser.

22. The laser driven light source of claim 19 wherein a spectral selectivity of the reflection region of the second optical element is chosen to select a desired spatial mode and wavelength of the second CW laser beam generated by the second diode laser.

23. The laser driven light source of claim 19 wherein the second optical element comprises a beam combining element configured to combine the CW laser beam and the second CW laser beam.

24. A method for generating stabilized broadband light, the method including:
a) generating a continuous wave (CW) laser beam with a laser;
b) passing a portion of the CW laser beam to an output;
c) selecting a spatial mode and wavelength of the CW sustaining laser beam by reflecting a portion of the CW laser beam back to the laser, thereby generating CW sustaining light with radiant flux and spectral shape stable as a function of time at the output of the laser; and
d) optically coupling the output of the laser to a gas-filled bulb, wherein the generated CW sustaining light sustains a CW plasma in the gas-filled bulb, thereby emitting light with radiant flux and spectral shape stable as a function of time.

25. The method of claim 24, wherein the CW laser beam is a single mode laser beam.

26. The method of claim 24, wherein the selecting the spatial mode and wavelength of the CW laser beam by reflecting the portion of the selected spatial mode and wavelength of the CW laser beam back to the laser comprises configuring a shape of a reflection region.

27. The method of claim 26, further comprising selecting a spectral selectivity of the reflection region to select a desired spatial mode and wavelength of the CW laser beam.

28. The method of claim 26, wherein the selecting the spatial mode and wavelength of the CW laser beam by reflecting the portion of the selected spatial mode and wavelength of the CW laser beam back to the laser comprises reflecting from an optical grating mirror comprising the reflection region.

29. The method of claim 26, further comprising selecting a dimension of the reflection region to be smaller than a dimension of the CW laser beam.

30. The method of claim 26, further comprising selecting a size of the reflection region to select a desired spatial mode and wavelength of the CW laser beam.

31. The method of claim 26, wherein a shape of the reflection region is chosen to select a desired spatial mode and wavelength of the CW laser beam generated by the laser.

32. The method of claim 26, further comprising selecting a spectral selectivity of the reflection region so that a desired portion of a spectrum of the CW laser beam is reflected.

33. The method of claim 24, further comprising positioning an optical element in a far field of the laser beam.

34. The method of claim 24, further comprising generating a second CW laser beam with a second laser; selecting a second spatial mode and second wavelength of the second laser beam by reflecting a portion of the second CW laser beam back to the second laser, thereby generating CW sustaining light with radiant flux and spectral shape stable as a function of time at the output of the second laser; and optically coupling the output of the second laser to the gas-filled bulb.
